(19) United States
(12) Patent Application Publication
(10) Pub. No.: US 2024/0262300 A1
(43) Pub. Date: Aug. 8, 2024

(54) LAYERED BASE PLATE

(71) Applicant: Ford Global Technologies, LLC, Dearborn, MI (US)

(72) Inventors: Matthew B. Rutman, Westland, MI (US); Stuart C. Salter, White Lake, MI (US); Michael M. Azzouz, Farmington, MI (US); Dan Ritz, Windsor (CA); David Brian Glickman, Southfield, MI (US)

(21) Appl. No.: 18/107,300

(22) Filed: Feb. 8, 2023

(51) Int. Cl. B60R 13/01; B60R 16/02

(52) U.S. Cl. CPC B60R 13/01; B60R 16/02; B60R 2011/004; B60R 2011/0049

(57) ABSTRACT

A base plate for an accessory attachment system includes a first member made from a first material and a second member made from a second material, wherein the first and second members are attached to each other in an overlapping arrangement. At least one of the first and second members include a plurality of apertures, wherein the plurality of apertures comprise at least mounting apertures and power connection apertures configured to interface with an accessory.

### TECHNICAL FIELD

This disclosure relates generally to a base plate that is used to secure accessories within a cargo or work area, more particularly, to a base plate that has a layered construction.

### BACKGROUND

Vehicles transport various types of cargo. A user can, for example, rely on a vehicle to transport accessories, such as containers and tools, to and from a jobsite. The accessories that need to be transported can vary based on the tasks the user performs at the jobsite. Support surfaces in cargo or work areas may be configured to securely support the accessories.

### SUMMARY

In some aspects, the techniques described herein relate to a base plate for an accessory attachment system, including: a first member made from a first material; a second member made from a second material, wherein the first and second members are attached to each other in an overlapping arrangement; and wherein at least one of the first and second members include a plurality of apertures, wherein the plurality of apertures comprise at least mounting apertures and power connection apertures configured to interface with an accessory.

In some aspects, the techniques described herein relate to a base plate for an accessory attachment system, wherein the first material is the same as the second material.

In some aspects, the techniques described herein relate to a base plate for an accessory attachment system, wherein the first material and the second material comprise metal or plastic.

In some aspects, the techniques described herein relate to a base plate for an accessory attachment system, wherein the first material is different from the second material.

In some aspects, the techniques described herein relate to a base plate for an accessory attachment system, wherein one of the first and second materials is metal and the other of the first and second materials is plastic.

In some aspects, the techniques described herein relate to a base plate for an accessory attachment system, including a support frame attached to one of the first member and the second member.

In some aspects, the techniques described herein relate to a base plate for an accessory attachment system, wherein the support frame comprises a ladder structure having at least first and second rails and a plurality of cross members spaced apart from each other and extending between the first and the second rails.

In some aspects, the techniques described herein relate to a base plate for an accessory attachment system, wherein the first member comprises a top plate and the second member comprises a bottom plate that is fixed to the top plate.

In some aspects, the techniques described herein relate to a base plate for an accessory attachment system, wherein the top plate includes a first set of mounting apertures and a first set of power connection apertures, and wherein the bottom plate includes a second set of mounting apertures and a second set of power connection apertures, wherein the first and second sets of mounting apertures are aligned with each other, and wherein the first and second sets of power connection apertures are aligned with each other when the top and bottom plates are attached to each other.

In some aspects, the techniques described herein relate to a base plate for an accessory attachment system, wherein the top plate and the bottom plate both include mounting apertures that are formed within recessed mounting pockets and that are aligned with each other, and wherein the top plate and the bottom plate both include power connection apertures that are formed within recessed power pockets and that are aligned with each other.

In some aspects, the techniques described herein relate to a base plate for an accessory attachment system, wherein the top plate is spot welded to the bottom plate with a plurality of discrete welds that are located at least in the recessed mounting pockets and the recessed power pockets.

In some aspects, the techniques described herein relate to a base plate for an accessory attachment system, wherein the plurality of apertures additionally include a plurality of locking apertures configured to receive a lock member to lock the accessory to the base plate, wherein the locking apertures, the mounting apertures, and the power connection apertures are all separate from each other.

In some aspects, the techniques described herein relate to a base plate for an accessory attachment system, including a ladder support frame attached to a lower surface of the bottom plate such that the bottom plate is positioned between the ladder support frame and the top plate.

In some aspects, the techniques described herein relate to a base plate for an accessory attachment system, wherein the first member comprises a corrugated plate and the second member comprises a plurality of inserts that are attached to the corrugated plate.

In some aspects, the techniques described herein relate to a base plate for an accessory attachment system, wherein the corrugated plate includes a plurality of troughs that include power connection apertures, and wherein the plurality of inserts are positioned to overlap the troughs and include power connection apertures that align with the power connection apertures formed in the troughs.

In some aspects, the techniques described herein relate to a base plate for an accessory attachment system, wherein the corrugated plate includes a plurality of raised portions that alternate with the plurality of troughs, and wherein the mounting apertures are formed within the raised portions.

In some aspects, the techniques described herein relate to a base plate for an accessory attachment system, wherein at least one of the plurality of inserts provides a connection interface for a tie-down anchor.

In some aspects, the techniques described herein relate to a base plate for an accessory attachment system, wherein the corrugated plate includes a plurality of raised portions that alternate with the plurality of troughs, and wherein at least one of the plurality of inserts extends beyond an upper surface of the raised portions to provide a low friction support surface.

In some aspects, the techniques described herein relate to a base plate for an accessory attachment system, including a ladder support frame attached to a lower surface of the corrugated plate.

In some aspects, the techniques described herein relate to a method of forming a base plate for an accessory attachment system, comprising: forming a first member from a first material; forming a second member from a second material; attaching the first and second members to each other in an overlapping arrangement; and providing at least one of the first and second members with a plurality of apertures, wherein the plurality of apertures comprise at least mounting apertures and power connection apertures configured to interface with an accessory.

The embodiments, examples and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

### BRIEF DESCRIPTION OF THE FIGURES

The various features and advantages of the disclosed examples will become apparent to those skilled in the art from the detailed description. The figures that accompany the detailed description can be briefly described as follows:

FIG. 1A illustrates a perspective view of a vehicle having a cargo bed equipped with base plates that can be used to secure an accessory according to an exemplary aspect of the present disclosure.

FIG. 1B illustrates a perspective view of a van having a cargo area equipped with base plates that can be used to secure accessories according to an exemplary aspect of the present disclosure.

FIG. 1C illustrates a top view of a vehicle where the base plate can be slid out of the cargo area to make the base plate more accessible.

FIG. 2 illustrates a perspective view of an example accessory to be attached to the base plate.

FIG. 3 illustrates a top perspective view of a first example of a base plate made from a layered construction.

FIG. 4 is a bottom perspective view of the base plate of FIG. 3.

FIG. 5A is a perspective view of a bottom plate of the base plate of FIG. 3.

FIG. 5B is a magnified view of a mounting foot opening in the bottom plate of FIG. 5A.

FIG. 5C is a magnified view of a power connection opening in the bottom plate of FIG. 5A.

FIG. 5D is a magnified view of a button locking opening in the bottom plate of FIG. 5A.

FIG. 6A is a perspective view of a top plate of the base plate of FIG. 3.

FIG. 6B is a magnified view of a mounting foot opening in the top plate of FIG. 6A.

FIG. 6C is a magnified view of a power connection opening in the top plate of FIG. 6A.

FIG. 6D is a magnified view of a button locking opening in the top plate of FIG. 6A.

FIG. 7A is an exploded view of a second example of a base plate made from a layered construction.

FIG. 7B is a perspective view of the assembled base plate of FIG. 7A.

FIG. 8A is a perspective view of one example of a corrugated layer and plastic insert layer with an opening.

FIG. 8B is a section view of FIG. 8A at the opening.

FIG. 9A is a section view of another example of an opening.

FIG. 9B is a section view of another example of an opening.

FIG. 9C is a section view of another example of an opening.

FIG. 9D is a section view of another example of an opening.

### DETAILED DESCRIPTION

This disclosure details a base plate made from a layered construction where the base plate is used with an accessory attachment system for a vehicle or stationary application. The base plate provides an attachment interface for securing the accessories in place within a cargo or work area. Various types of accessories can be secured to the vehicle through the attachment interface provided by the base plate. The number and positions of base plates can be adjusted for particular vehicles or particular needs.

There are often situations where it would be useful for the vehicle owner to be able to switch between accessories to enable different functional capabilities, or to temporarily remove an accessory or module to allow the module or its contents to be used off the vehicle, then reattach the module once the desired operation or task is completed. It is also useful to be able to provide power connection interfaces on the base plates to allow charging of accessories such as power tools, for example. The subject disclosure provides a base plate construction that has high strength and low weight, and which allows a mechanical attachment to the vehicle via a quick connect/disconnect capability, while also providing various power connection interfaces for charging and locking features to make sure that the accessories are securely held in place.

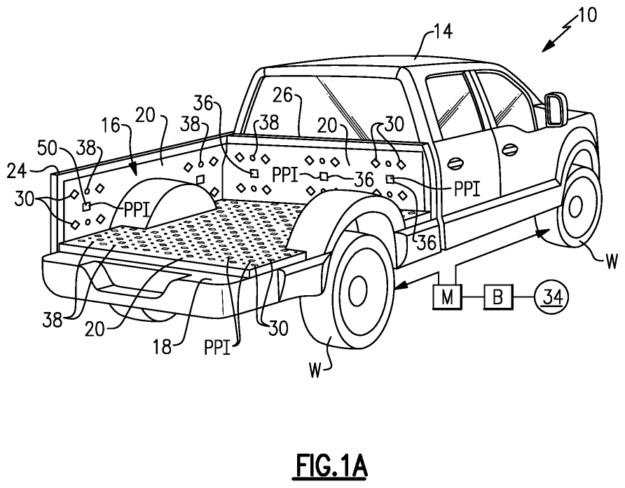

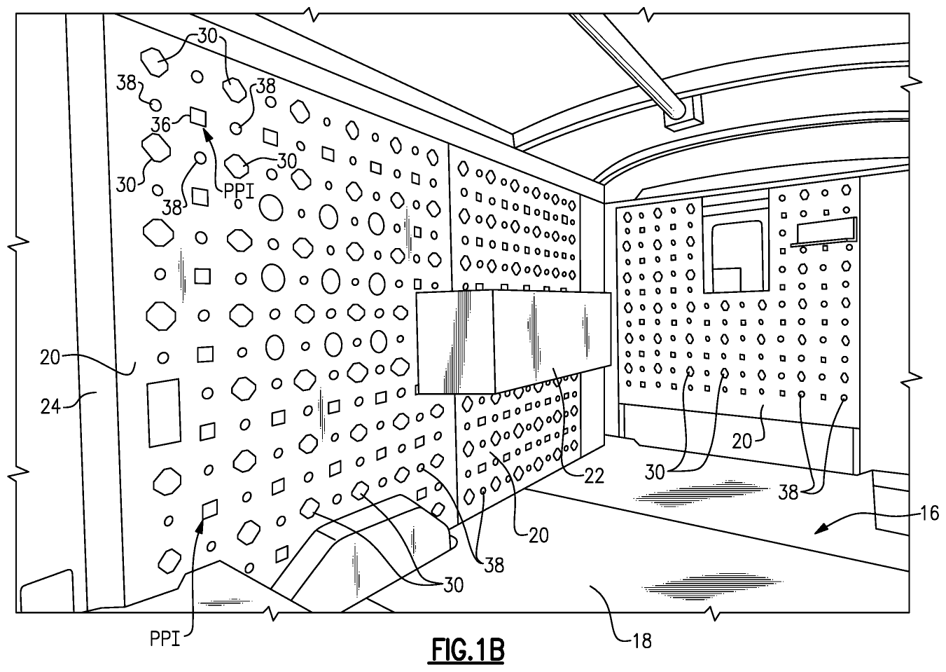

With reference to FIGS. 1A and 2, a vehicle 10 includes a passenger compartment 14 and a cargo bed 16 that is aft of the passenger compartment 14. The cargo bed 16 has a floor 18. In this example, the vehicle 10 is a pickup truck. However, the vehicle 10 could be another type of vehicle in another example, such as a car, van, sport utility vehicle, etc. FIG. 1B shows an example of a van that incorporates a base plate with an accessory attachment and locking system.

The example vehicle 10 is an electrified vehicle and, in particular, a battery electric vehicle (BEV). In another example, the vehicle 10 could be another type of electrified vehicle, such as a plug-in hybrid electric vehicle (PHEV), or a conventional internal combustion engine vehicle.

In particular, the example vehicle 10 includes an electrified powertrain capable of applying a torque from an electric machine M (e.g., an electric motor) to drive a pair of wheels W. The vehicle 10 can include a traction battery pack B, which powers the electric machine M and, potentially, other electrical loads of the vehicle 10.

In the exemplary embodiment, a plurality of base plates 20 are used to support one or more accessories and/or modules 22. In one example, the cargo bed 16 is defined by a pair of side walls 24 (only one is shown in FIG. 1A for purposes of clarity), a rear wall 26, and a tailgate T (FIG. 1C). In one example, the base plates 20 are secured directly to walls 24, 26 and/or to the floor 18 of the cargo bed 16 by fastening, welding, etc., at a first connection interface. In another example shown in FIG. 1C, the base plates 20 can be supported for sliding movement within the cargo bed 16 on rails R or other types of sliding structures. The accessories and/or modules 22 can be secured to the vehicle 10 by engaging one or more of the base plates 20 via a second connection interface between the accessory 22 and the base plate 20. The accessories/modules 22 can comprise a lockable storage box that holds tools, a container, a refrigerator, etc. For example, the accessory 22 could be a lockable container having a lid L attached within hinges H (FIG. 2), and which includes a compartment for storing power tools or other items that require power or data connection.

As shown in FIGS. 1A-1C, the base plates 20 include a plurality of openings or apertures 30. As shown in FIG. 2, an example accessory 22 comprises a lockable container or box 22 that includes one or more mounting feet 32. The box 22 can engage the base plate 20 using an attachment system comprising the plurality of apertures 30 and the mounting feet 32 that cooperate to provide a mechanical connection interface. In this example, the base plates 20 provide the apertures 30 and the accessories 22 include the feet 32. This could be rearranged, however, such that one or all of the feet 32 extend from the base plates 20 and the accessories 22 provide some or all of the apertures 30. The apertures 30 are spaced upwardly from the floor 18 or side wall 24, 26 by an open gap such that the feet 32 from the accessory 22 can be easily inserted into the base plate 20 to attach the accessory 22 to the base plate 20. The accessory 22 can then be removed and replaced with a different accessory 22 as needed. The user can, for example, hold tools for a certain type of job within the accessory 22. When the user needs to work on a different second type of job, the user can swap the accessory 22 for another accessory 22 having specialized tools for the second type of job.

As discussed above, in this example, the accessory 22 comprises a lockable box that is mechanically coupled to the vehicle 10 via the base plate 20. The accessory 22 could additionally include a power connection interface 34 that would be able to supply power to the box itself as well as any tools/devices within the box that would require charging. The power connection interface 34 is powered from the vehicle power supply, such as the battery pack B, for example. Any devices within the lockable box, e.g. rechargeable tools, could be recharged when set within the box and coupled to a charging interface associated with the power connection interface 34 between the accessory 22 and the base plate 20.

In one example, the base plate 20 can also be plugged into either 12V vehicle power or other power sources via a variety of connections/outlets. These power sources supply power to charge or power the accessories 22 via the power supply connection interface 34 associated with the base plate 20. Each accessory 22 has an accessory power interface (API) as shown in FIG. 2. At least some, or all, of the mounting locations for an accessory 22 have a charging interface with a plate power interface (PPI) as shown in FIGS. 1A-1B. The API and the PPI can be a direct electrical connection or can be via an inductive wireless charging connection. The PPI receives vehicle power via the vehicle power supply or other power source.

The subject disclosure provides for a base plate 20 that is made from a layered construction to provide a high strength support while not adversely affecting weight. The base plate 20 can comprise a side mounted attachment interface between the accessory box 22 and the base plate 20 or can comprise a bottom mounted attachment. In the side mounted example, the feet 32 are on the side of the accessory 20 and the base plate 20 is configured to be positioned within the vehicle cargo bed 16 at the side wall 24 that extends upwardly from the floor surface of the truck bed in a vertical direction as shown in FIG. 1A, or at the side wall 24 in the van of FIG. 1B. In the bottom mounted example, the bottom of the accessory 22 includes the feet 32 which fit into apertures 30 formed in a base plate 20 that is located on the floor 18 of the truck or van.

The apertures 30 are formed within the base plate 20 and comprise a plate attachment interface. The base plate 20 also includes an opening or aperture 36 for the PPI and an opening or aperture 38 for a locking feature that allows the accessory 22 to be securely locked to the base plate 20. These apertures 30, 36, 38 are provided at multiple locations on the base plate 20, and are formed in a desired pattern on the base plate 20 to allow for the accessories 22 to be mounted in various different locations and orientations as needed. When the accessory box 22 is attached to the base plate 20, the feet 32 are inserted into the corresponding apertures 30 to mechanically attach the accessory 22 to the base plate 20 in one of the plurality of mounting orientations. The accessory 22 can then be selectively detached from one mounting orientation on the base plate 20 such that the accessory 22 can immediately be reattached in a different one of the mounting orientations.

In one example, the box 22 is held in place by a mechanical locking system that is configured have a locked position where the accessory box 22 is prevented from being removed from the base plate 20 and an unlocked position where the accessory box 22 is allowed to be removed from the base plate 20. An example of such a locking system is found in application Ser. No. 17/993,345 filed on Nov. 23, 2022, which is assigned to the assignee of the subject application, and which is herein incorporated by reference. In one example, the locking mechanism comprises a button 40 that is resiliently biased to extend into the locking aperture 38 (FIGS. 1A-C) on the base plate 20 when the mounting feet 32 are fitted into the corresponding apertures 30 to provide the locked position.

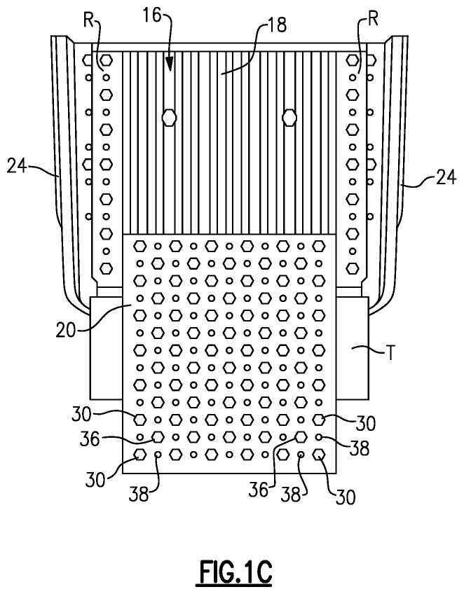

FIGS. 3-4, 5A-5D, and 6A-6D show a first example of a layered base plate 20 that includes the mounting feet apertures 30, the power connection apertures 36, and the locking apertures 38. The base plate 20 comprises a first member 42 made from a first material and a second member 44 made from a second material. The first 42 and second 44 members are attached to each other in an overlapping arrangement. FIG. 3 illustrates a top perspective view of the layered base plate 20 where the first member 42 can be seen. FIG. 4 illustrates a bottom perspective view of the layered base plate 20 where the second member 44 can be seen.

At least one of the first 42 and second 44 members include a plurality of apertures that comprise at least mounting apertures 30 for mounting feet 32 and power connection apertures 36 configured to interface with the power interface API on the accessory 22. In the example shown in FIGS. 3-4 both the first 42 and second 44 members include the mounting apertures 30 and the power connection apertures 36. Additionally, the first 42 and second 44 members of the base plate 20 may also include the locking apertures 38.

In one example, the first material for the first member 42 is the same as the second material for the second member 44. For example, the basic material of both the first 42 and second 44 member can be High-Strength Low-Alloy (HSLA) steel having a thickness of approximately 1.5 mm.

In another example, the basic material of both the first 42 and second 44 member can be plastic; however, a base plate 20 made from plastic would not be able to hold heavier loads. In another example, the first and second materials can be different from each other. For example, one of the first and second materials could be a metal material such as steel, and the other of the first and second materials could be plastic. This would present a hybrid configuration that would provide additional reinforcement.

As shown in FIG. 4, in one example, an additional support frame 50 is attached to one of the first member 42 and the second member 44. In this example, the support frame 50 comprises a ladder structure having at least first and second rails 52 and a plurality of cross members 54 spaced apart from each other and extending between the first and the second rails 52. The first and second rails 52 comprise side rails that extend in a longitudinal direction and the cross members 54 comprise the rungs that extend in a horizontal direction between the side rails. In one example, an additional pair of rails 56 are used to connect ends of the side rails to each other to form a box frame.

In one example, bearings 58 are attached to the side rails 52. The bearings 58 are spaced apart from each other along the length of the side rails 52 and are configured to cooperate with the rails R (FIG. 1C) such that the base plate 20 can be slid out of the cargo area 16. In one example, pins (not shown) are inserted through holes in the side rails 52 and the bearings 58 are mounted on the pins. The pins can be spot welded to the frame from the back side to increase the amount of load the pins can support.

In one example, the first member 42 comprises a top plate 42a and the second member 44 comprises a bottom plate 44a that is fixed to the top plate 42a. In one example, the plates 42a, 44a are formed from steel and are welded together. The two steel plates 42a, 44a combined with the ladder support frame 50 gives strength to the base plate 20 in a manner that provides high strength in a compact and light-weight design.

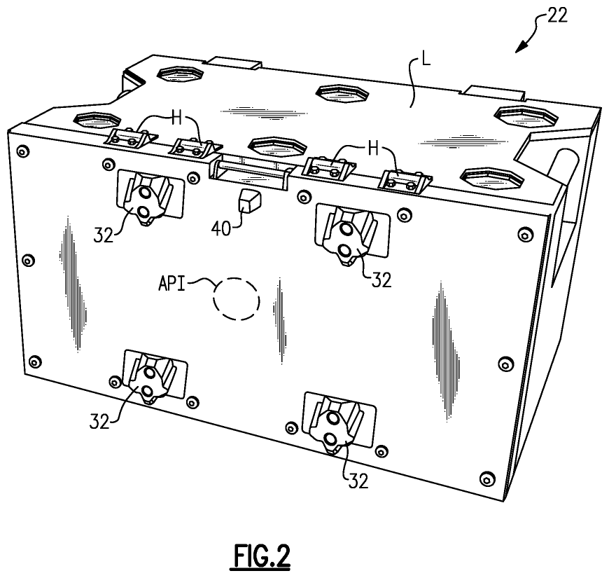

As shown in FIG. 5A, the bottom plate 44a comprises a generally flat plate body having a flat upper surface 60 (FIG. 5A) and a flat lower surface 62 (FIG. 4) facing opposite the upper surface. The bottom plate 44a includes mounting apertures 30, power connection apertures 36, and locking apertures 38 that extend through the thickness of the bottom plate 44a from the upper surface 60 to the lower surface 62.

In one example, the mounting apertures 30 of the bottom plate 44a are formed within recessed mounting pockets 64, the power connection apertures 36 are formed within recessed power connection pockets 66, and locking apertures 38 are formed within recessed locking pockets 68. FIG. 5B shows an example of a recessed mounting pocket 64 with a mounting aperture 30. FIG. 5C shows an example of a recessed power connection pocket 66 with a power connection aperture 36. FIG. 5D shows an example of a recessed locking pocket 68 with locking aperture 38.

In one example, the locking apertures 38, the mounting apertures 30, and the power connection apertures 36 are all separate from each other. In one example, each of the apertures 30, 36, 38 has a unique shape/configuration such that the apertures 30, 36, 38 can easily be identified and differentiated from each other by a user.

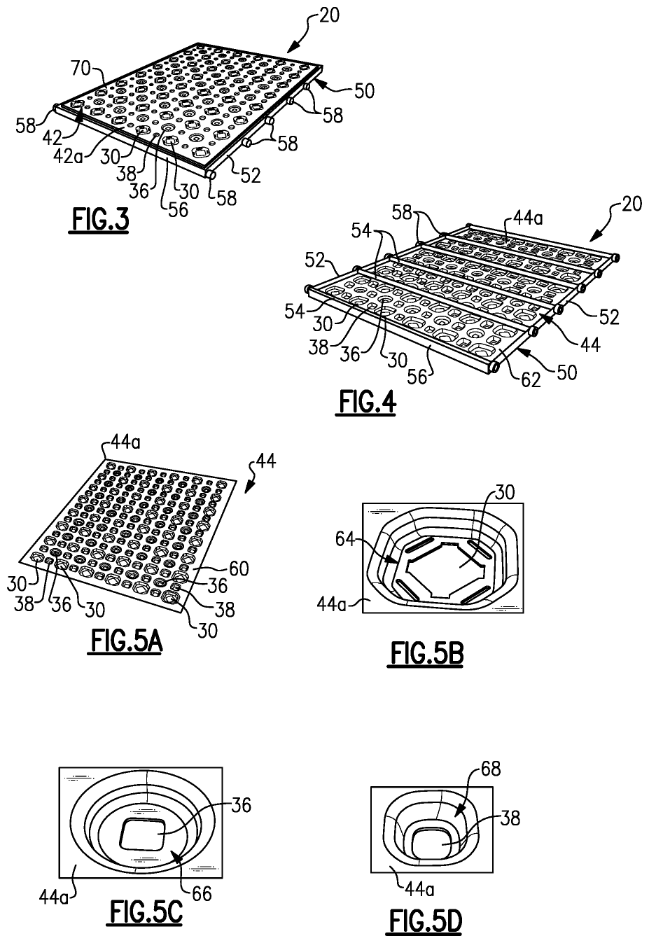

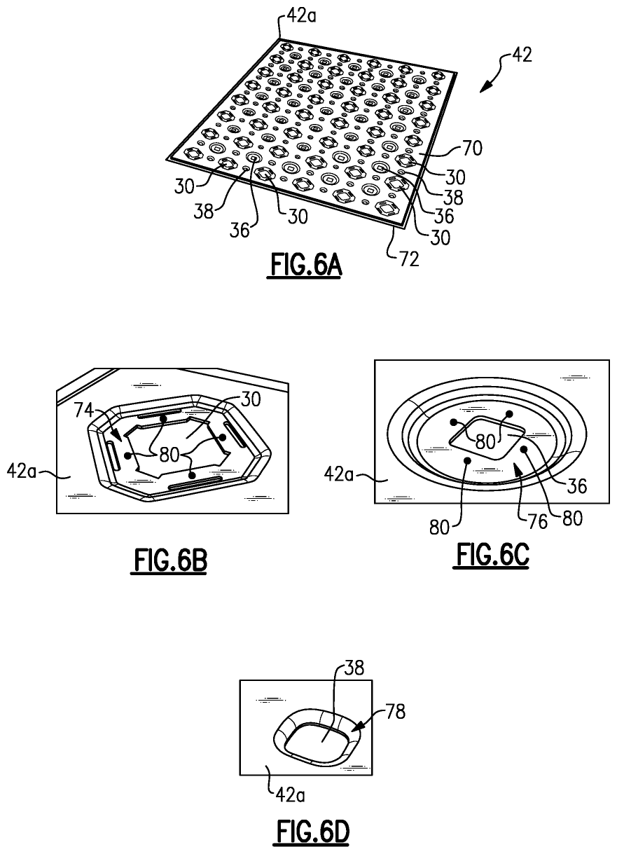

As shown in FIG. 6A, the top plate 42a comprises a generally flat plate body having a flat upper surface 70 and a flat lower surface 72 facing opposite the upper surface 70. The top plate 42a includes mounting apertures 30, power connection apertures 36, and locking apertures 38 that extend through the thickness of the top plate 42a from the upper surface 70 to the lower surface 72.

In one example, the mounting apertures 30 of the top plate 42a are formed within recessed mounting pockets 74, the power connection apertures 36 are formed within recessed power connection pockets 76, and locking apertures 38 are formed within recessed locking pockets 78. FIG. 6B shows an example of a recessed mounting pocket 74 with a mounting aperture 30. FIG. 6C shows an example of a recessed power connection pocket 76 with a power connection aperture 36. FIG. 6D shows an example of a recessed locking pocket 78 with locking aperture 38. In one example, each of the apertures 30, 36, 38 is separate from the others and has a unique shape/configuration such that the apertures 30, 36, 38 can easily be identified and differentiated from each other by a user.

The mounting apertures 30, power connection apertures 36, and locking apertures 38 of the top plate 42a and the bottom plate 44a are aligned with each other. As such, the recessed mounting pockets 64, the recessed power connection pockets 66, and the recessed locking pockets 68 of the top plate 42a fit within, i.e. are received within, corresponding recessed mounting pockets 74, recessed power connection pockets 76, and recessed locking pockets 78 of the bottom plate 44a.

Once the top plate 42a and the bottom plate 44a have been fit against each other, the top plate 42a is spot welded to the bottom plate 44a with a plurality of discrete welds 80 that are at least located in the recessed pockets at areas of contact between the plates. FIGS. 6B and 6C show examples of the locations for the spot welds 80. In one example, the spot welding is done from a first side using a jig that provides the second side and a robotic arm. In this example, the spot welds 80 are done on the top surface 70 (less depth for robotic welder) in the pattern shown in FIGS. 6B and 6C. The discrete small spot welds 80 in multiple places gives a strength to the base plate 20 while not having any heat deformation.

In one example, once the plates 42a, 44a are attached to each other, the ladder support frame 50 is then attached to a lower surface of the bottom plate 44a such that the bottom plate 44a is positioned between the ladder support frame 50 and the top plate 42a. The support frame 50 can be welded to the base plate 20, or adhesive or fasteners could also be used.

FIGS. 7A-B show another example of a base plate 20 made from a layered construction. In this example, the first member 42 comprises a corrugated plate 42b and the second member 44 comprises a plurality of inserts 44b that are attached to the corrugated plate 42b. In one example, the corrugated plate 42b is comprised of a metal/steel material and the inserts 44b are comprised of a plastic material. The corrugated plate 42b includes a plurality of troughs 82 a plurality of raised portions 84 that alternate with the plurality of troughs 82. The troughs 82 include power connection apertures 36 and any associated wiring needed to provide a power connection interface through the base plate 20 and to the accessory 22. The plurality of inserts 44b are positioned to overlap and cover the troughs 82. The inserts 44b include power connection apertures 36 that align with the power connection apertures 36 formed in the troughs 82. In one example, the mounting apertures 30 are formed within the raised portions 84 of the corrugated plate 42b.

In one example, the inserts 44b are snap fit to the corrugated plate 42b to cover the troughs 82 and provide the layered construction. Once the plate 42b and inserts 44b are attached to each other, the ladder support frame 50 (FIG. 4) is attached a lower surface of the corrugated plate 42b.

The plastic metal hybrid construction of the configuration shown in FIGS. 7A-B has a very low investment. The corrugated plate 42b can be made from steel or aluminum that is rolled in a constant section, and is then cut and punched to length. The section is scalable for different widths and is stronger than stamping and does not require any welding. The plastic insert strips, which snap into the metal, are robust as well as being serviceable and scalable. The inserts 44b can allow sliding of cargo and can eliminate “catch points” that could dislodge cargo. Additionally, the insert strip can be customized with texture, color-coding, different spacing, etc. within the same base plate 20.

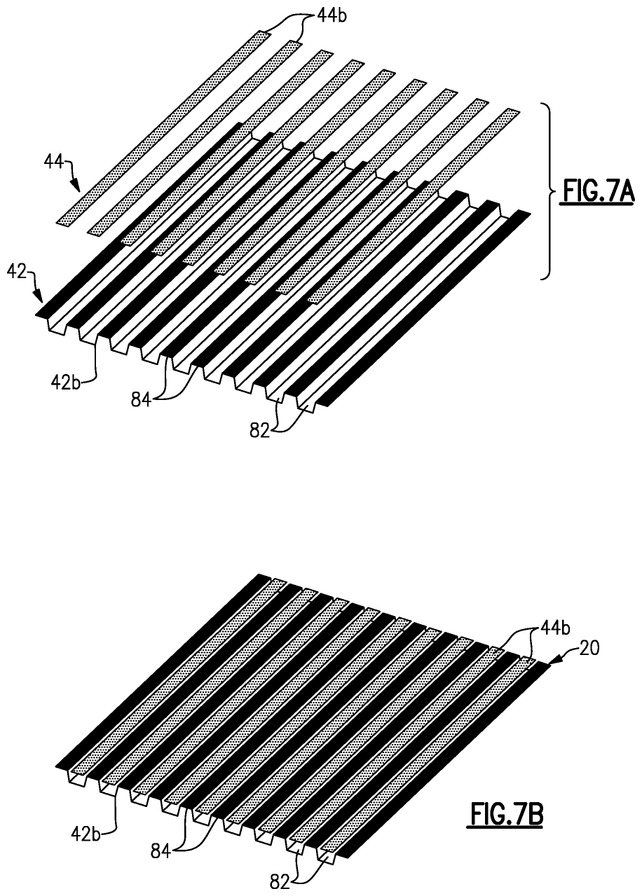

FIG. 8A is a perspective view of one example of a corrugated plate 42b and plastic insert layer 44b with a power connection aperture 36. FIG. 8B is a section view of FIG. 8A at the power connection aperture 36. The insert 44b is fit within the trough 82 and is flush with the upper surface of the raised portion 84. The apertures 36 in the insert 44b and the plate 42b are aligned within each other. In one example, upper 86 and lower 88 surfaces of the insert 44b are angled/tapered in a direction toward a center of the aperture 36 to facilitate insertion through the aperture 36.

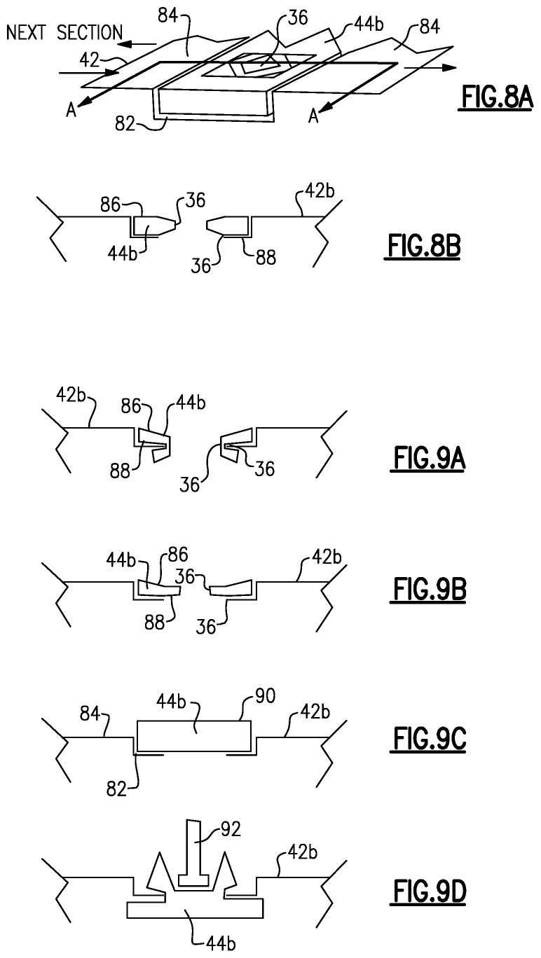

FIG. 9A shows an example of a wrapped plastic insert 44b that extends around the edge of the opening 36 and below the plate 42b. This can be done with living hinges or carets, for example, for greater load capacity. In this example, the upper surface 86 is slanted/tapered toward the aperture 36 to facilitate insertion through the aperture 36.

FIG. 9B shows an example of an insert 44b that has an upper surface 86 that is initially slanted/tapered toward the aperture 36 and then flattens out immediately around the aperture 36. The bottom surface 88 also is initially slanted/tapered toward the aperture 36 and then flattens out immediately around the aperture 36. As such, the insert 44b is thinner immediately about the aperture 36 and then gradually increases in thickness.

The inserts and apertures can be tailored to provide different geometry and lighter loads, as well as support specialized cargo.

FIG. 9C shows a configuration where the insert 44b extends beyond an upper surface of the raised portions 84 to provide a low friction support surface 90. This also provides an option to skip the provision of an aperture for specialized fleets that do not need to have exposed holes in a metal surface. This raises the plastic inserts above metal surface to act as friction reducer such that it is easier to slide loads and to protect the metal structure.

FIG. 9D shows an example where the inserts 44b provide a connection interface for a tie-down anchor 92. FIG. 9D shows a bottom-up steel tie-down anchor 92 which can be used permanently or temporarily by carets which can allow strips to be removed and replaced multiple times while holding tight to steel floor structure.

The preceding description is exemplary rather than limiting in nature. Variations and modifications to the disclosed examples may become apparent to those skilled in the art that do not necessarily depart from the essence of this disclosure. Thus, the scope of protection given to this disclosure can only be determined by studying the following claims.

What is claimed is:

1. A base plate for an accessory attachment system, comprising:
a first member made from a first material;
a second member made from a second material, wherein the first and second members are attached to each other in an overlapping arrangement; and
wherein at least one of the first and second members include a plurality of apertures, wherein the plurality of apertures comprise at least mounting apertures and power connection apertures configured to interface with an accessory.

2. The base plate of claim 1, wherein the first material is the same as the second material.

3. The base plate of claim 2, wherein the first material and the second material comprise metal or plastic.

4. The base plate of claim 1, wherein the first material is different from the second material.

5. The base plate of claim 4, wherein one of the first and second materials is metal and the other of the first and second materials is plastic.

6. The base plate of claim 1, including a support frame attached to one of the first member and the second member.

7. The base plate of claim 6, wherein the support frame comprises a ladder structure having at least first and second rails and a plurality of cross members spaced apart from each other and extending between the first and the second rails.

8. The base plate of claim 1, wherein the first member comprises a top plate and the second member comprises a bottom plate that is fixed to the top plate.

9. The base plate of claim 8, wherein the top plate includes a first set of mounting apertures and a first set of power connection apertures, and wherein the bottom plate includes a second set of mounting apertures and a second set of power connection apertures, wherein the first and second sets of mounting apertures are aligned with each other, and wherein the first and second sets of power connection apertures are aligned with each other when the top and bottom plates are attached to each other.

10. The base plate of claim 8, wherein the top plate and the bottom plate both include mounting apertures that are formed within recessed mounting pockets and that are aligned with each other, and wherein the top plate and the bottom plate both include power connection apertures that are formed within recessed power pockets and that are aligned with each other.

11. The base plate of claim 10, wherein the top plate is spot welded to the bottom plate with a plurality of discrete welds that are located at least in the recessed mounting pockets and the recessed power pockets.

12. The base plate of claim 8, wherein the plurality of apertures additionally include a plurality of locking apertures configured to receive a lock member to lock the accessory to the base plate, wherein the locking apertures, the mounting apertures, and the power connection apertures are all separate from each other.

13. The base plate of claim 8, including a ladder support frame attached to a lower surface of the bottom plate such that the bottom plate is positioned between the ladder support frame and the top plate.

14. The base plate of claim 1, wherein the first member comprises a corrugated plate and the second member comprises a plurality of inserts that are attached to the corrugated plate.

15. The base plate of claim 14, wherein the corrugated plate includes a plurality of troughs that include power connection apertures, and wherein the plurality of inserts are positioned to overlap the troughs and include power connection apertures that align with the power connection apertures formed in the troughs.

16. The base plate of claim 15, wherein the corrugated plate includes a plurality of raised portions that alternate with the plurality of troughs, and wherein the mounting apertures are formed within the raised portions.

17. The base plate of claim 14, wherein at least one of the plurality of inserts provides a connection interface for a tie-down anchor.

18. The base plate of claim 14, wherein the corrugated plate includes a plurality of raised portions that alternate with the plurality of troughs, and wherein at least one of the plurality of inserts extends beyond an upper surface of the raised portions to provide a low friction support surface.

19. The base plate of claim 14, including a ladder support frame attached to a lower surface of the corrugated plate.

20. A method of forming a base plate for an accessory attachment system, comprising:
forming a first member from a first material;
forming a second member from a second material;
attaching the first and second members to each other in an overlapping arrangement; and
providing at least one of the first and second members with a plurality of apertures, wherein the plurality of apertures comprise at least mounting apertures and power connection apertures configured to interface with an accessory.
